(19) United States
(12) Patent Application Publication
(10) Pub. No.: US 2020/0341069 A1
(43) Pub. Date: Oct. 29, 2020

(54) METHOD FOR PRODUCING SEPARATOR AND APPARATUS FOR PRODUCING SEPARATOR

(71) Applicant: Sumitomo Chemical Company, Limited, Tokyo (JP)

(72) Inventors: Yusuke KON, Niihama-shi (JP); Wataru SAKUMA, Niihama-shi (JP); Tatsuya SAKAMOTO, Niihama-shi (JP)

(21) Appl. No.: 16/857,301

(22) Filed: Apr. 24, 2020

(30) Foreign Application Priority Data
Apr. 25, 2019 (JP) 2019-084517

(51) Int. Cl. G01R 31/3835; H01M 10/0587

(52) U.S. Cl. CPC G01R 31/3835; H01M 10/0587

(57) ABSTRACT

Achieved is a highly efficient separator inspecting step. An inspection for a defect is carried out with respect to at least part of an unwound part, and quality of a roll is determined in accordance with a result of the inspection.

This Nonprovisional application claims priority under 35 U.S.C. § 119 on Patent Application No. 2019-084517 filed in Japan on Apr. 25, 2019, the entire contents of which are hereby incorporated by reference.

### TECHNICAL FIELD

The present invention relates to (i) a method for producing a separator and (ii) an apparatus for producing a separator.

### BACKGROUND ART

Nonaqueous electrolyte secondary batteries such as lithium-ion secondary batteries are in wide use as batteries for personal computers, mobile telephones, portable information terminals, and the like. Lithium-ion secondary batteries, in particular, are drawing attention as batteries that help reduce CO₂ emissions and that contribute to energy saving, as compared to conventional secondary batteries.

A process for producing a nonaqueous electrolyte secondary battery separator and other separators includes a separator inspecting step of detecting a defect in a separator (see Patent Literature 1).

### CITATION LIST

### Patent Literature

### [Patent Literature 1]

Japanese Patent Application Publication Tokukai No. 2016-133325 (Publication date: Jul. 25, 2016)

### SUMMARY OF INVENTION

### Technical Problem

A process for producing a separator commonly includes a step of transferring a separator via a roller so as to prepare a roll. In a case where a foreign object having adhered to a surface of the roller is in contact with the separator that is being transferred, periodic defects may be developed in a machine direction of the separator which machine direction is parallel to a direction in which the separator is transferred.

Conventionally, all the separator is inspected in the separator inspecting step regardless of whether defects in the separator are periodically developed in the separator. To this end, all the separator is unwound from the roll. As a result, an area of the separator to be inspected is made extremely large, and an operation to unwind the separator is made complicated. This causes a problem of inefficiency in the separator inspecting step (described earlier).

An object of an aspect of the present invention is to achieve a highly efficient separator inspecting step.

### Solution to Problem

In order to attain the object, a method for producing a separator in accordance with an aspect of the present invention includes: an inspection step of inspecting the separator, the inspection step including the steps of: a) transferring the separator via a plurality of rollers so as to prepare a roll obtained by winding the separator; b) unwinding part of the separator from the roll; c) carrying out an inspection for a defect with respect to at least part of an unwound part of the separator; and d) determining quality of the roll in accordance with a result of the inspection.

According to the method, defects that are periodically developed in a machine direction of the separator can be detected without the need to unwind all the separator from the roll. Thus, in a case where periodic defects are expected to be developed in the separator of the roll, the inspection step can be carried out with high efficiency.

An apparatus for producing a separator in accordance with an aspect of the present invention includes: a winding device for unwinding the separator from a roll obtained by winding the separator; an inspection performing device for carrying out an inspection for a defect with respect to at least part of an unwound part of the separator; and a cutting device for cutting the separator so as to remove a part of the separator which part has been subjected to the inspection, the winding device winding back, to the roll, a part of the unwound part of the separator which part is continuous with the roll after the separator is cut.

With the configuration, the separator can be partially unwound from the roll in a case where at least part of an unwound part of the separator is inspected for a defect by partially unwinding the separator from the roll. The configuration also allows the cutting device to cut, from an uninspected part of the separator, the inspected part of the separator to be discarded. This makes it possible to achieve an apparatus for producing the separator, the apparatus being suitable for a highly efficient inspection step.

### Advantageous Effects of Invention

An aspect of the present invention makes it possible to achieve a highly efficient separator inspecting step.

### BRIEF DESCRIPTION OF DRAWINGS

FIG. 1 illustrates a plurality of examples in each of which a defect is produced in a separator.

FIG. 2 is a view schematically illustrating a basic principle of a withstand voltage inspection carried out with respect to a separator.

FIG. 3 is another view schematically illustrating a basic principle of a withstand voltage inspection carried out with respect to a separator.

FIG. 4 is a front view schematically illustrating a first step of a method for producing a separator in accordance with Embodiment 1 of the present invention.

FIG. 5 is a front view schematically illustrating a second step of the method for producing a separator in accordance with Embodiment 1 of the present invention.

FIG. 6 is a front view schematically illustrating a third step of the method for producing a separator in accordance with Embodiment 1 of the present invention.

FIG. 7 is a conceptual diagram for specifically describing determination of quality in a fourth step of the method for producing a separator in accordance with Embodiment 1 of the present invention.

FIG. 8 is a front view schematically illustrating a fifth step of the method for producing a separator in accordance with Embodiment 1 of the present invention.

FIG. 9 is a front view schematically illustrating a sixth step of the method for producing a separator in accordance with Embodiment 1 of the present invention.

FIG. 10 is a front view illustrating a separator, separator pieces, and a roll prepared by winding the separator pieces.

FIG. 11 is a perspective view schematically illustrating a step 1 of a method for producing slit separators in accordance with Embodiment 2 of the present invention.

FIG. 12 is a front view schematically illustrating a step 2 of the method for producing slit separators in accordance with Embodiment 2 of the present invention.

FIG. 13 is a front view schematically illustrating a step 3 of the method for producing slit separators in accordance with Embodiment 2 of the present invention.

FIG. 14 is a front view illustrating slit separators and a roll prepared by winding the slit separators.

FIG. 15 is a perspective view schematically illustrating an inspection device and an inspection method each for inspecting a separator in accordance with Variation 1.

FIG. 16 is a front view schematically illustrating an inspection device and an inspection method each for inspecting a separator in accordance with Variation 2.

(a) of FIG. 17 is a perspective view illustrating a specific configuration example of the inspection device of FIG. 16. (b) of FIG. 17 is a side view of the inspection device of FIG. 16 when seen from a machine direction of the separator.

FIG. 18 has perspective views illustrating respective configurations of two devices each serving as a comparative example of the inspection device illustrated in FIG. 17.

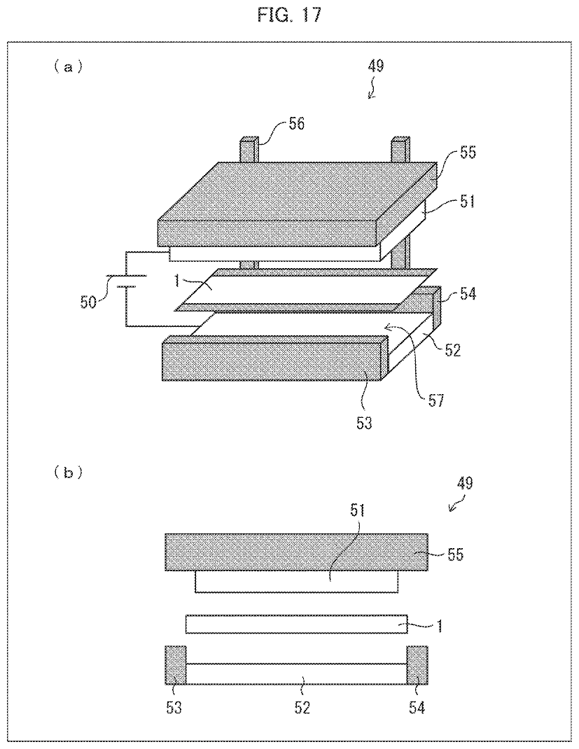

(a) of FIG. 19 is a perspective view illustrating a variation of the inspection device of FIG. 16. (b) of FIG. 19 is a side view of the inspection device of FIG. 16 when seen from the machine direction of the separator.

(a) of FIG. 20 is a perspective view illustrating another variation of the inspection device of FIG. 16. (b) of FIG. 20 is a side view of the inspection device of FIG. 16 when seen from the machine direction of the separator.

### DESCRIPTION OF EMBODIMENTS

Before discussing embodiments of the present invention, the following description will discuss a withstand voltage inspection carried out with respect to a separator for detecting a defect in the separator.

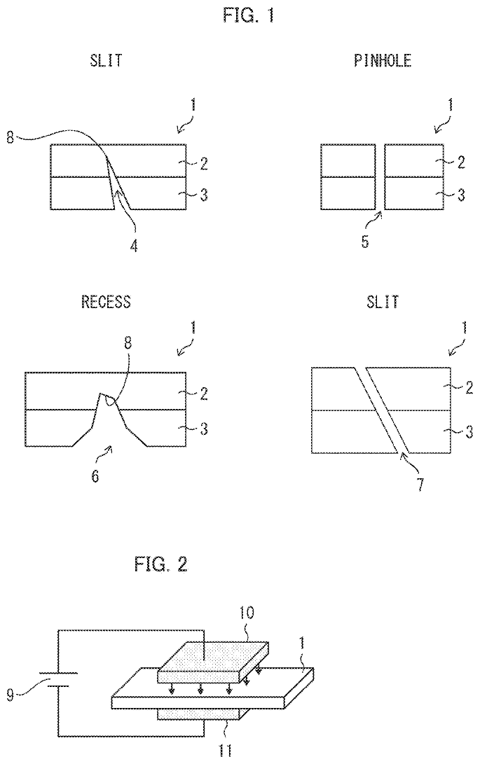

FIG. 1 illustrates a plurality of examples in each of which a defect is produced in a separator 1.

The separator 1 includes a base material 2 and a functional layer 3 provided to one of surfaces of the base material 2. Examples of the base material 2 include a porous film that contains polyolefin as a main component. Examples of the functional layer 3 include a heat-resistant film that contains aramid as a main component, a film that contains ceramic as a main component, and a film that contains polyvinylidene fluoride (PVdF) as a main component. Note that the functional layer 3 can be provided to each of the surfaces of the base material 2.

A defect may be produced in the separator 1 due to, for example, a foreign object produced during a process for producing the separator 1. This makes it necessary to carry out, during production of the separator 1, an inspection for detecting the defect.

Examples of the defect in the separator 1 include a slit 4, a pinhole 5, a recess 6, and a slit 7. FIG. 1 illustrates respective states of the defects, which are the slit 4, the pinhole 5, the recess 6, and the slit 7, in cross-sectional view of the separator 1.

The slit 4 is a notch made in a thickness direction of the separator 1 so as not to be through the separator 1, and has a bottom part 8. In a case where one of surfaces of the separator 1 is viewed, the slit 4 (notch) has a length long enough to be in a circle having a diameter of not less than 50 μm and not more than 200 μm.

The pinhole 5 is a hole that is through the separator 1. The pinhole 5 has a diameter of not less than 5 μm and not more than 200 μm.

The recess 6 is provided to any of the surfaces of the separator 1 and is a depression having the bottom part 8. In a case where a surface of the separator 1 in which surface the recess 6 is provided is viewed, the recess 6 has a size large enough to be in a circle having a diameter of 10 μm.

In FIG. 1, the recess 6 is provided to a functional layer 3 side surface of the separator 1, and the bottom part 8 is provided to the base material 2. Note, however, that the recess 6 may alternatively be provided to a base material 2 side surface of the separator 1. The bottom part 8 may be provided to the base material 2 or to the functional layer 3 regardless of whether the recess 6 is provided to the functional layer 3 side surface of the separator 1 or to the base material 2 side surface of the separator 1.

The slit 7 is a notch made so as to be through the separator 1. In a case where one of the surfaces of the separator 1 is viewed, the slit 7 (notch) has a length long enough to be in a circle having a diameter of not less than 50 μm and not more than 200 μm.

An optical inspection has been conventionally carried out with respect to the separator 1 so that a defect in the separator 1 is detected. The optical inspection is carried out with respect to the separator 1 by capturing an image of the separator 1 with use of a camera so as to detect a defect in the separator 1 by the image thus captured. Note, however, that the optical inspection carried out with respect to the separator 1 has the following disadvantages (A) and (B).

(A) The optical inspection carried out with respect to the separator 1 is unsuitable for detecting a defect in the separator 1 while transferring the separator 1. The first reason is that, since a single period of image capture carried out with use of a camera is a relatively long time, the camera may fail to take a photograph of a defect in the separator 1 in a case where the separator 1 is transferred at a high speed. The second reason is that, in order that a captured image of an extremely small defect (e.g., the pinhole 5) in the separator 1 is prevented from being blurred, such a defect needs to be detected by (i) making a speed at which the separator 1 is transferred extremely low or (ii) stopping transfer of the separator 1.

(B) The optical inspection carried out with respect to the separator 1 is unsuitable for detecting the recess 6 provided to the separator 1. This is because of the following reason. Specifically, existence of the bottom part 8 may prevent the recess 6 from clearly existing in a captured image. In this case, the recess 6 is difficult to detect even by observing the captured image. Furthermore, the optical inspection carried out with respect to the separator 1 is unsuitable for detecting the slit 7 provided to the separator 1. This is because of the following reason. Specifically, the slit 7, which is not in a form of holes that are continuous in a vertical direction, may prevent the slit 7 from clearly existing in a captured image. In this case, the slit 7 is difficult to detect even by observing the captured image. The slit 4 having the bottom part 8 is more difficult to detect by the optical inspection.

Under the circumstances, it is possible to carry out a withstand voltage inspection with respect to the separator 1 in order to detect a defect in the separator 1.

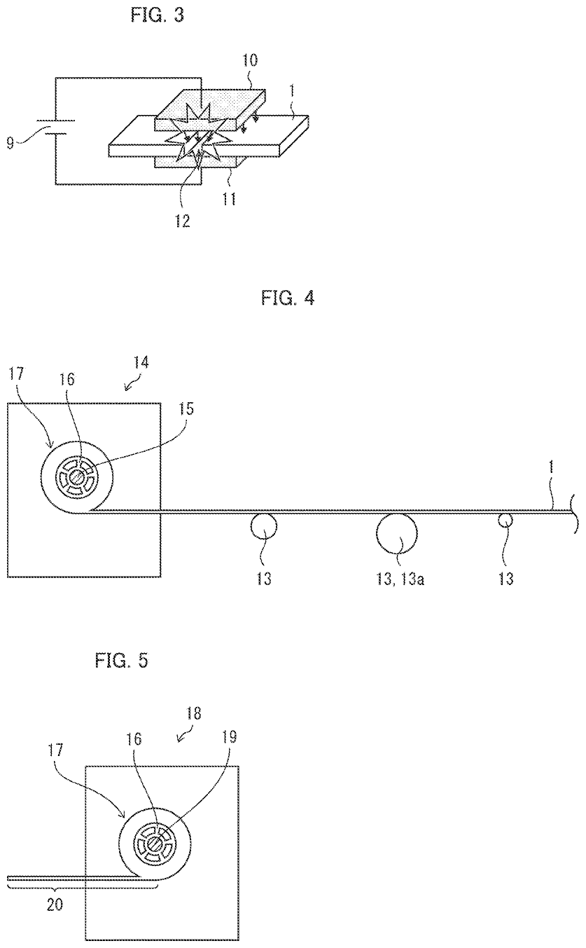

FIGS. 2 and 3 are each a view schematically illustrating a basic principle of the withstand voltage inspection carried out with respect to the separator 1. The withstand voltage inspection is carried out with respect to the separator 1 by causing the separator 1 to be sandwiched by (a) an electrode 10 connected with a positive electrode of an electric power source 9 and (b) an electrode 11 connected with a negative electrode of the electric power source 9, while applying a voltage of the electric power source 9. The electrode 10 and the electrode 11 function as a single capacitor, and a part of the separator 1 which part is located between the electrode 10 and the electrode 11 functions as a dielectric. In the examples shown in FIGS. 2 and 3, there is air between the electrode 10 and the electrode 11. In this case, the air located between the electrode 10 and the electrode 11 also functions as the dielectric.

FIG. 2 illustrates the example in which no defect is produced in the part of the separator 1 which part is located between the electrode 10 and the electrode 11. In a case where no defect is produced in the part of the separator 1 which part is located between the electrode 10 and the electrode 11, the electrode 10 and the electrode 11 are insulated from each other with the separator 1.

FIG. 3 illustrates the example in which a defect 12 is produced in the part of the separator 1 which part is located between the electrode 10 and the electrode 11. A part of the separator 1 in which part the defect 12 is produced has a lower resistance value than a part of the separator 1 in which part no defect 12 is produced. Thus, in a case where the defect 12 is produced in the part of the separator 1 which part is located between the electrode 10 and the electrode 11, an electric field between the electrode 10 and the electrode 11 concentrates in and near the defect 12, so that the electrode 10 and the electrode 11 are electrically connected with each other.

Thus, in a case where (i) a voltage of the electric power source 9 is applied and (ii) the electrode 10 and the electrode 11 are electrically connected with each other while the separator 1 is sandwiched by the electrode 10 and the electrode 11, it is possible to detect that the defect 12 is produced in the part of the separator 1 which part is located between the electrode 10 and the electrode 11.

The above principle makes it possible to carry out the withstand voltage inspection with respect to the separator 1 in order to detect the defect 12 in the separator 1. Unlike the optical inspection carried out with use of a camera, the withstand voltage inspection carried out with respect to the separator 1 makes it unnecessary to capture an image of the defect 12. This allows the defect 12 that is extremely small (e.g., the pinhole 5 (see FIG. 1)) to be detected in the separator 1 even in a case where the separator 1 is transferred at a relatively high speed. Thus, the withstand voltage inspection carried out with respect to the separator 1 is suitable for detecting the defect 12 in the separator 1 while transferring the separator 1. Furthermore, unlike the optical inspection carried out with use of a camera, the withstand voltage inspection carried out with respect to the separator 1 makes it unnecessary to capture an image of the defect 12. This makes it easy to detect the slit 4 (see FIG. 1), the slit 7 (see FIG. 1), and the recess 6 (see FIG. 1). A speed at which the separator 1 is transferred is not limited to any particular speed, but can be set to not less than 1 m/min and not more than 200 m/min, and is preferably not less than 30 m/min and not more than 100 m/min.

A voltage value of the electric power source 9 is determined in accordance with, for example, a resistance value of the separator 1, an interval at which the electrode 10 and the separator 1 are spaced, and an interval at which the electrode 11 and the separator 1 are spaced. The voltage value of the electric power source 9, the interval at which the electrode 10 and the separator 1 are spaced, and the interval at which the electrode 11 and the separator 1 are spaced only need to be a condition under which the principle of the withstand voltage inspection can be embodied. Note, however, that the voltage value of the electric power source 9 can be set to, for example, not less than 1.8 kV and not more than 3 kV, and can alternatively be set to not less than 2.1 kV and not more than 2.4 kV. Note also that the electrode 10 and the electrode 11 are preferably spaced at an interval of approximately 100 μm. That is, it is possible to suitably employ a condition that the interval at which the electrode 10 and the electrode 11 are spaced is set to 100 μm and the voltage value of the electric power source 9 is set to not less than 1.8 kV and not more than 3 kV. Furthermore, since a voltage having a desired value is preferably continuously applied to each of the electrode 10 and the electrode 11, a direct-current voltage is more preferably applied to each of the electrode 10 and the electrode 11 than an alternating-current voltage, as illustrated in FIGS. 2 and 3. Continuous application of a direct-current voltage allows the separator 1 to be transferred at a higher speed. Furthermore, in a case where a voltage having a greater value is applied to each of the electrode 10 and the electrode 11, the electrode 10 and the electrode 11 are electrically connected with each other even in a case where a resistance value between the electrode 10 and the electrode 11 is high. Thus, in order to avoid a change in condition under which the electrode 10 and the electrode 11 are electrically connected with each other, the direct-current voltage is preferably a constant voltage. Note that air, which is commonly said to have a withstand voltage of 3 kV/mm, is easily increased and decreased due to a temperature, a humidity, and scattered foreign objects. Thus, from the viewpoint of reproducibility, the withstand voltage inspection is desirably carried out in a clean room environment in which a temperature and a humidity are constant and fewer foreign objects are scattered.

In FIGS. 2 and 3, the electrode 10 and the separator 1 are not in contact with each other, and the electrode 11 and the separator 1 are in contact with each other. Alternatively, the electrode 10 and the separator 1 can be in contact with each other, and/or the electrode 11 and the separator 1 does not need to be in contact with each other.

In a case where the electrode 10 and the separator 1 are not in contact with each other, it is possible to reduce damage to a surface of the electrode 10. This allows the electrode 10 to be durable. Same applies to a case where the electrode 11 and the separator 1 are not in contact with each other. In a case where the electrode 10 and the separator 1 are in contact with each other, it is unnecessary to consider an interval at which the electrode 10 and the separator 1 are spaced. This makes it easy to carry out the withstand voltage inspection with respect to the separator 1. Same applies to a case where the electrode 11 and the separator 1 are in contact with each other.

### Embodiment 1

A method for producing the separator 1 in accordance with Embodiment 1 of the present invention includes an inspection step. In the inspection step, an inspection including at least the following first to sixth steps is carried out.

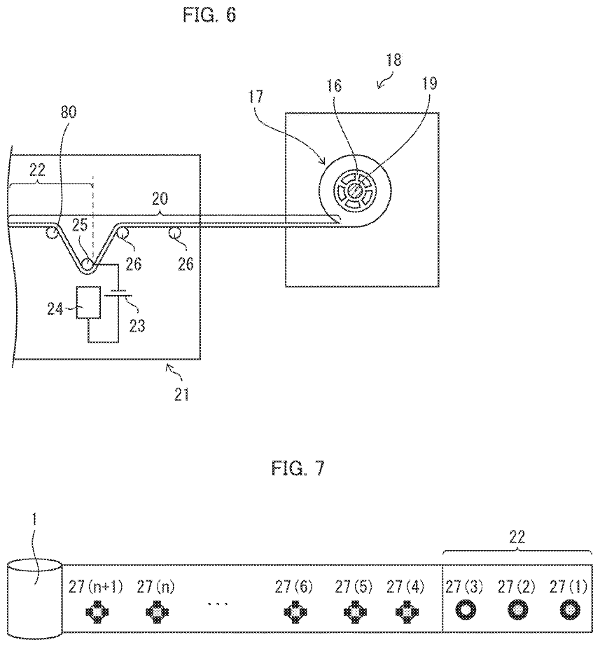

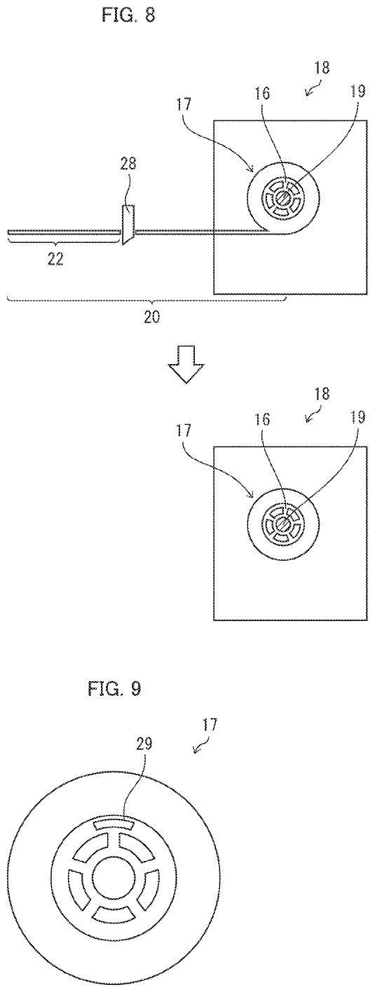

FIG. 4 is a front view schematically illustrating the first step. FIG. 5 is a front view schematically illustrating the second step. FIG. 6 is a front view schematically illustrating the third step. FIG. 7 is a conceptual diagram for specifically describing determination of quality in the fourth step. FIG. 8 is a front view schematically illustrating the fifth step. FIG. 9 is a front view schematically illustrating the sixth step. In FIGS. 4 and 5, the separator 1 is wound and unwound from bottom. Note, however, that winding and unwinding of the separator 1 are not particularly limited. The separator 1 can alternatively be wound and unwound from top.

In the first step, the following processes are carried out. The separator 1 is transferred via a plurality of rollers 13. A winding device 14 is provided at a destination to which the separator 1 is transferred via the plurality of rollers 13. The winding device 14 includes a rotation mechanism 15 that rotates in a direction substantially parallel to a direction in which the separator 1 is transferred. To the rotation mechanism 15, a core 16 is provided. The winding device 14 causes the rotation mechanism 15 to rotate the core 16, so that the separator 1 is wound around the core 16. Thus, a roll 17 in which the separator 1 is wound around the core 16 is prepared.

Assume here that a foreign object adheres to a surface of a roller 13. In this case, the foreign object is in contact with a surface of the separator 1 to be transferred. This may develop a defect in the separator 1. According to Embodiment 1, a defect in the separator 1 which defect is caused by a foreign object having adhered to the surface of the roller 13 is referred to as a roller-derived defect. The foreign object having adhered to the surface of the roller 13 is in contact with the surface of the separator 1 per rotation of the roller 13. Thus, roller-derived defects are developed at regular intervals in the direction in which the separator 1 is transferred. In other words, in a case where a foreign object adheres to the surface of the roller 13, a plurality of roller-derived defects may be periodically developed in the separator 1 in a machine direction of the separator 1. Examples of a roller-derived defect include the slit 4 (see FIG. 1), the pinhole 5 (see FIG. 1), the recess 6 (see FIG. 1), the slit 7 (see FIG. 1), and the defect 12 (see FIGS. 2 and 3).

In the second step, the following processes are carried out. A winding device 18 unwinds part of the separator 1 from the roll 17. The roll 17 is provided to a rotation mechanism 19 of the winding device 18. The rotation mechanism 19 rotates in a direction in which the separator 1 is sent out from the core 16. This causes the core 16 to unwind the separator 1. A part of the separator 1 which part has been unwound in the second step is referred to as an unwound part 20. A combination of the rotation mechanism 19 and the winding device 18 can be a combination of the rotation mechanism 15 and the winding device 14. Alternatively, the combination of the rotation mechanism 19 and the winding device 18 can be prepared separately from the combination of the rotation mechanism 15 and the winding device 14.

Note here that a length for which to unwind the separator 1 from the roll 17, i.e., a length of the unwound part 20 of the separator 1 which unwound part 20 extends in the machine direction of the separator 1 is preferably not less than a length of a circumference of a roller 13a that has a maximum diameter of the plurality of rollers 13. A reason for this will be described later.

In the third step, the following processes are carried out. An inspection performing device 21 is used to inspect at least part of the unwound part 20 for any defect such as a roller-derived defect. FIG. 6 illustrates an example in which an inspected part 22, which is part of the unwound part 20, is subjected to the withstand voltage inspection (described earlier) carried out with respect to the separator 1 for detecting a defect in the separator 1. The inspection performing device 21 includes an electric power source 23, an electrode 24, an electrode 25, a plurality of rollers 26, and a roller 80. The electric power source 23, the electrode 24, and the electrode 25 correspond to the electric power source 9 (see FIGS. 2 and 3), the electrode 10 (see FIGS. 2 and 3), and the electrode 11 (see FIGS. 2 and 3), respectively. FIG. 6 illustrates a case where a direct-current voltage is used. Alternatively, either a direct-current voltage or an alternating-current voltage can be applied to the electrode 24 and the electrode 25. In FIG. 6, the electrode 24 is connected with a positive electrode of the electric power source 23, and the electrode 25 is connected with a negative electrode of the electric power source 23. Alternatively, the electrode 25 can be connected with the positive electrode of the electric power source 23, and the electrode 24 can be connected with the negative electrode of the electric power source 23. In FIG. 6, the unwound part 20 is transferred via the plurality of rollers 26 and the roller 80, and the inspected part 22 is transferred to a space between the electrode 24 and the electrode 25, so that the inspected part 22 is subjected to the withstand voltage inspection. Note that the roller 80 is provided downstream of the electrode 25 in the inspected part 22 and serves as a transfer roller via which to transfer the separator 1. The configuration allows an extremely small defect (e.g., the pinhole 5 (see FIG. 1)) to be detected in the separator 1 even in a case where the separator 1 is transferred at a relatively high speed via the plurality of rollers 26 and the roller 80. Thus, the withstand voltage inspection carried out with respect to the separator 1 is suitable for detecting a defect in the separator 1 while transferring the separator 1. However, an inspection of the inspected part 22 in the third step is not limited to the withstand voltage inspection carried out with respect to the separator 1, but can be alternatively the optical inspection carried out with respect to the separator 1, or another inspection carried out with respect to the separator 1 for detecting a defect in the separator 1.

Note here that the separator 1 that is unwound from the roll 17 in the second step for a length that is not less than the length of the circumference of the roller 13a that has a maximum diameter of the plurality of rollers 13 has the following advantages. In this case, a roller-derived defect that occurs in the separator 1 is easily located in the unwound part 20. In a case where a part of the unwound part 20 which part has a length as long as or longer than the circumference of the roller 13a is inspected as the inspected part 22 in the third step, a roller-derived defect is easily detected. This allows the inspection to be carried out in the third step with higher accuracy.

Without regarding the plurality of rollers 26 as rollers that are present in the process for producing the separator 1, Embodiment 1 discusses an example in which only the plurality of rollers 13 are present in the process for producing the separator 1. In view of the advantages described earlier, in a case where a roller that has a larger diameter than the roller 13a is present in the process for producing the separator 1, the separator 1 is preferably unwound from the roll 17 for a length that is not less than a length of a circumference of that roller. That is, the separator 1 is preferably unwound from the roll 17 for a length that is not less than a length of a circumference of a roller that has a maximum diameter of the rollers that are present in the process for producing the separator 1. The separator 1 can be unwound from the roll 17 for a length that is at least twice or at least three times a length of a circumference of a roller that has a maximum diameter of the rollers that are present in the process for producing the separator 1. In a case where the length for which the separator 1 is unwound from the roll 17 is set to at least twice a length of a circumference of a roller that has a maximum diameter, detected defects are easily regarded as periodic defects.

In the fourth step, the following processes are carried out. Quality of the roll 17 is determined in accordance with a result of the inspection carried out with respect to the inspected part 22 through the third step. For example, quality of the roll 17 is specifically determined such that (i) the roll 17 that has the separator 1 in which no defect has been detected in the inspected part 22 is regarded as a non-defective product and (ii) the roll 17 that has the separator 1 in which a defect has been detected in the inspected part 22 is regarded as a defective product.

According to the above-described mechanism through which the roller-derived defects are developed, the roller-derived defects are periodically developed in the separator 1 in the machine direction of the separator 1 in such an order as follows: defects 27 (1), 27 (2), . . . , 27 (n), 27 (n+1), . . . . According to the inspection carried out with respect to the inspected part 22 in the third step, the defects 27 (1), 27 (2), and 27 (3) can be detected. It is possible to estimate that the defects 27 (4), 27 (5), . . . are highly likely to be developed in a part, different from the inspected part 22, of the separator 1 in which the defects 27 (1), 27 (2), and 27 (3) have been detected in the inspected part 22, without the need to inspect that part. Thus, the separator 1 in which the defects 27 (1), 27 (2), and 27 (3) have been detected in the inspected part 22 can be regarded as a defective product that has roller-derived defects.

In the fifth step, the following processes are carried out. All the separator 1 of the roll 17 that has been regarded as a defective product in the fourth step is discarded. Furthermore, at least the inspected part 22 of the roll 17 that has been regarded as a non-defective product in the fourth step is cut with use of a cutting device 28 so as to be separated from another part of the separator 1, and a cut part is discarded. In a case where a foreign object has adhered to a surface of the roller 80 via which to transfer the inspected part 22, a defect that is unique to the inspected part 22 may be developed in the inspected part 22. In a case where the inspected part 22 is discarded, a part in which a defect may be developed due to a foreign object having adhered to the surface of the roller 80 can be removed from the separator 1. Furthermore, in a case where a change in physical property of the inspected part 22 may be caused by the inspection carried out in the third step, a part in which a change in physical property may be caused by the inspection can be removed from the separator 1 by discarding the inspected part 22. Note that a roller 26 is desirably a roller that is different in diameter from the rollers used in the other processes described above. In a case where the roller 26 is different in diameter from the other roller, even in a case where periodic defects occur from the roller 26, it is possible to determine, by measuring intervals at which the periodic defects occur in the machine direction, that a poor withstand voltage is caused by the roller 26.

In the fifth step, in a case where the unwound part 20 that has been unwound from the roll 17 partially remains after the inspected part 22 is cut, the partially remaining unwound part 20 is wound back by the winding device 18. The rotation mechanism 19 rotates in a direction opposite to a direction in which the separator 1 is unwound in the second step. This causes the core 16 to wind back the unwound part 20.

In the sixth step, the following processes are carried out. To the roll 17 that has been regarded as a non-defective product in the fourth step, a label 29 indicating that the roll 17 is a non-defective product is attached. The label 29 can be attached to the roll 17 with use of a device or manually. To the roll 17 that has been regarded as a defective product in the fourth step, a label indicating that the roll 17 is a defective product can be attached. The label 29 includes information indicating whether the roll 17 is a non-defective product. The label 29 can also include other information, e.g., information that is associated with a system (not illustrated) and is necessary for checking, in the system, the information indicating whether the roll 17 is a non-defective product. This makes it possible to understand, from the label 29, whether the roll 17 is a non-defective product.

The label 29 can further include information on the roll 17 which information has been revealed after the third step, such as a result of the inspection of the roll 17 and an overall length of the separator 1 of the roll 17. This makes it possible to specifically understand, from the label 29, information on the roll 17 which information has been revealed after the third step.

The sixth step can be carried out after the fourth step and before the fifth step.

According to the above method, defects that are periodically developed in the machine direction of the separator 1, such as roller-derived defects can be detected without the need to unwind all the separator 1 from the roll 17. This makes it possible to expect that periodic defects are developed in the separator 1 of the roll 17, so that the inspection step can be carried out with high efficiency.

An apparatus for producing the separator 1 in accordance with Embodiment 1 of the present invention includes an inspection device. The inspection device at least includes (i) the winding device 18 that unwinds the separator 1 from the roll 17, (ii) the inspection performing device 21 that inspects, for a defect, the separator 1 that has been unwound, and (iii) the cutting device 28 that cuts the separator 1 that has been inspected. The winding device 18 is configured to wind back, to the roll 17, a part of the separator 1 that has been unwound, the part being continuous with the roll 17 after the separator 1 is cut. Configurations of the apparatus for producing the separator 1 in accordance with Embodiment 1 of the present invention except for those of the winding device 18, the inspection performing device 21, and the cutting device 28 can be achieved by a known technique, and a specific description thereof is therefore omitted here. With the configuration, the separator 1 can be partially unwound from the roll 17 in a case where at least part of the unwound part 20 is inspected for a defect by partially unwinding the separator 1 from the roll 17. The configuration also allows the cutting device 28 to cut, from an uninspected part of the separator 1, the inspected part 22 to be discarded. This makes it possible to achieve an apparatus for producing the separator 1, the apparatus being suitable for a highly efficient inspection step. Note that it is possible to (i) combine, with use of, for example, a tape, (a) the inspected part 22 to be discarded and (b) the separator to be subsequently inspected, without discarding the inspected part 22 immediately after the inspected part 22 is inspected and (ii) use the inspected part 22 as a transfer separator piece to be used to carry out the withstand voltage inspection with respect to the subsequent separator. This reduces a feeding operation for transferring the subsequent separator, so that the withstand voltage inspection can be carried out with respect to the separator with high efficiency.

### Embodiment 2

A method for producing slit separators 32 in accordance with Embodiment 2 of the present invention includes at least the following steps 1 to 3.

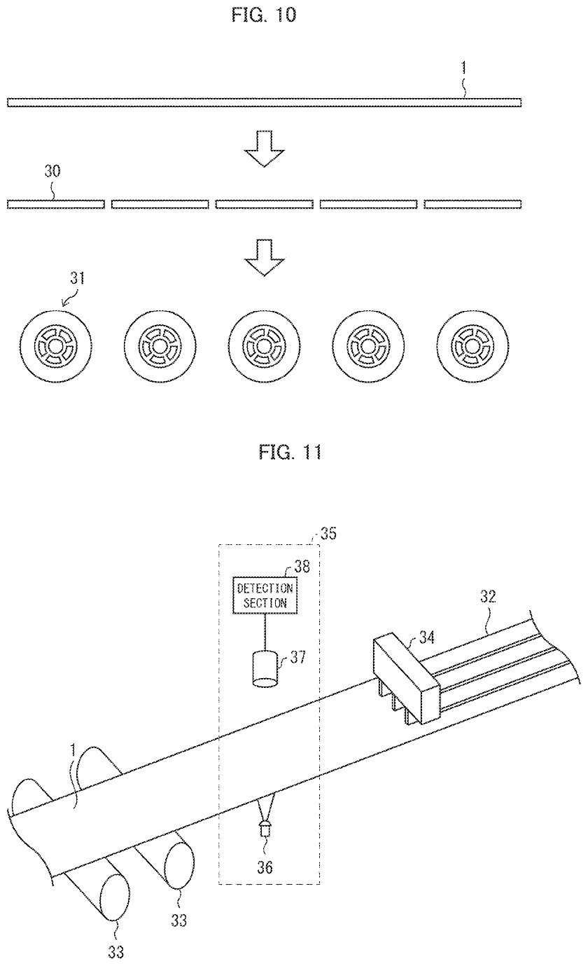

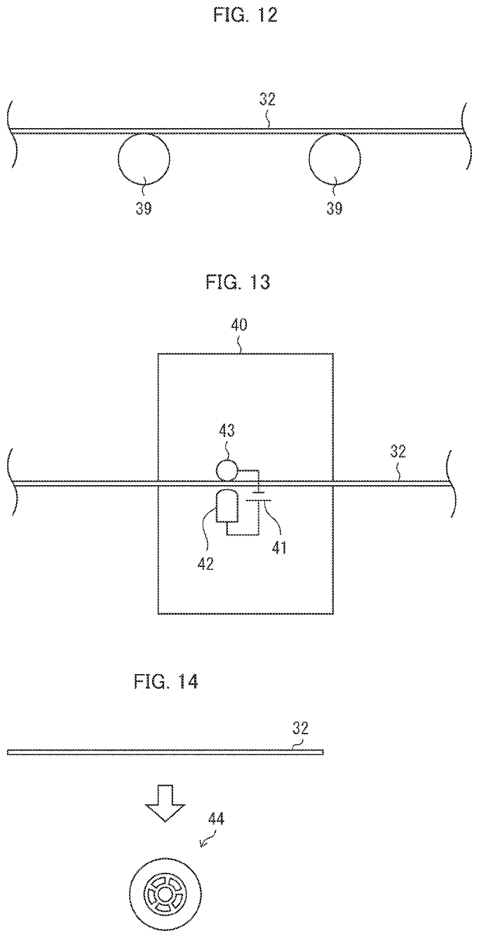

FIG. 11 is a perspective view schematically illustrating the step 1. FIG. 12 is a front view schematically illustrating the step 2. FIG. 13 is a front view schematically illustrating the step 3.

In the step 1, the following processes are carried out. A separator 1 is transferred via a plurality of rollers 33. A slitting device 34 is provided at a destination to which the separator 1 is transferred via the plurality of rollers 33. The slitting device 34 slits the separator 1 into the slit separators 32 in a direction in which the separator 1 is transferred, i.e., a machine direction of the separator 1.

In a transfer path of the separator 1, a preinspection device 35 is provided upstream of the slitting device 34. The preinspection device 35 inspects the separator 1 for a defect before the separator 1 is slit. The preinspection device 35 includes (i) a light source 36 that illuminates the separator 1, (ii) a camera 37 with which to capture an image of the separator 1 that is illuminated by the light source 36, and (iii) a detection section 38 configured to detect a defect in the separator 1 from the image that has been captured with the camera 37. The preinspection device 35 is a device for carrying out an optical inspection with respect to the separator 1 for detecting a defect in the separator 1.

In the step 2, the following processes are carried out. The slit separators 32 are transferred via a plurality of rollers 39. Assume here that a foreign object adheres to a surface of a roller 39. In this case, the foreign object is in contact with surfaces of the slit separators 32 to be transferred. This may develop a defect in the slit separators 32. According to Embodiment 2, a defect in the slit separators 32 which defect is caused by a foreign object having adhered to the surface of the roller 39 is referred to as a roller-derived defect. The foreign object having adhered to the surface of the roller 39 is in contact with the surfaces of the slit separators 32 per rotation of the roller 39. Thus, roller-derived defects are developed at regular intervals in a direction in which the slit separators 32 are transferred. In other words, in a case where a foreign object adheres to the surface of the roller 39, a plurality of roller-derived defects may be periodically developed in the slit separators 32 in a machine direction of the slit separators 32. Examples of a roller-derived defect include the slit 4 (see FIG. 1), the pinhole 5 (see FIG. 1), the recess 6 (see FIG. 1), the slit 7 (see FIG. 1), and the defect 12 (see FIGS. 2 and 3).

In the step 3, the following processes are carried out. An inspection device 40 inspects, for a defect such as a roller-derived defect, the slit separators 32 that have been transferred via the plurality of rollers 39. FIG. 13 illustrates an example in which the slit separators 32 are subjected to a withstand voltage inspection similar to the withstand voltage inspection (described earlier) carried out with respect to the separator 1 for detecting a defect in the separator 1. The inspection device 40 includes an electric power source 41, an electrode 42, and an electrode 43. The electric power source 41, the electrode 42, and the electrode 43 correspond to the electric power source 9 (see FIGS. 2 and 3), the electrode 10 (see FIGS. 2 and 3), and the electrode 11 (see FIGS. 2 and 3), respectively. In FIG. 13, the slit separators 32 are transferred to a space between the electrode 42 and the electrode 43 via the plurality of rollers 39, so that the slit separators 32 are subjected to the withstand voltage inspection. This allows an extremely small defect (e.g., the pinhole 5 (see FIG. 1)) to be detected in the slit separators 32 even in a case where the slit separators 32 are transferred at a relatively high speed via the plurality of rollers 39. Thus, the withstand voltage inspection carried out with respect to the slit separators 32 is suitable for detecting a defect in the slit separators 32 while transferring the slit separators 32. However, an inspection of the slit separators 32 in the step 3 is not limited to the withstand voltage inspection carried out with respect to the slit separators 32, but can be alternatively an optical inspection carried out with respect to the slit separators 32, or another inspection carried out with respect to the slit separators 32 for detecting a defect in the slit separators 32.

An apparatus for producing the slit separators 32 in accordance with Embodiment 2 of the present invention includes (i) the slitting device 34 that prepares the slit separators 32 by slitting the separator 1, (ii) the (plurality of) rollers 39 via which to transfer the slit separators 32, and (iii) the inspection device 40 that inspects the slit separators 32 that have been transferred via the rollers 39. The apparatus for producing the slit separators 32 in accordance with Embodiment 2 of the present invention includes the preinspection device 35 that inspects the separator 1 before the separator 1 is slit. Configurations of the apparatus for producing the slit separators 32 in accordance with Embodiment 2 of the present invention except for those of the slitting device 34, the preinspection device 35, the rollers 39, and the inspection device 40 can be achieved by a known technique, and a specific description thereof is therefore omitted here.

Conventionally, a defect that has been developed in the separator 1 or in the slit separators 32 is not assumed to be detected downstream of the preinspection device 35 in a transfer path of the separator 1. According to the above method, it is possible to detect a defect such as a roller-derived defect by inspecting the slit separators 32 that have been transferred via the rollers 39. That is, a defect in the slit separators 32 which defect has been developed by a contact, with the slit separators 32, of a foreign object having adhered to surfaces of the rollers 39 via which to transfer the slit separators 32 can be detected in a process carried out after the separator 1 is slit. This makes it possible to allay a fear that the slit separators 32 in which the defect remains and which are low in quality may be shipped in a form of products. In addition, in a case where (i) the inspection carried out by the preinspection device 35 in the step 1 and (ii) the step 3 are combined, a defect that has been detected in the step 3 can be expected to be a roller-derived defect.

FIG. 14 is a front view illustrating the slit separators 32 and a roll 44 prepared by winding the slit separators 32. As in the case of the first step (see FIG. 4), the slit separators 32 are transferred via the rollers so that the roll 44 is prepared. As in the case of the second step (see FIG. 5), the slit separators 32 are partially unwound from the roll 44. As in the case of the third step (see FIG. 6), a part of the slit separators 32 which part has been unwound from the roll 44 is at least partially subjected to an inspection for a defect such as a roller-derived defect. As in the case of the fourth step (see FIG. 7), quality of the roll 44 is determined in accordance with a result of the inspection.

According to the above method, defects that are periodically developed in the machine direction of the slit separators 32, such as roller-derived defects can be detected without the need to unwind all the slit separators 32 from the roll 44. Thus, in a case where periodic defects are expected to be developed in the slit separators 32 of the roll 44, an inspection step can be carried out with high efficiency.

### Embodiment 3

The following description discuss, by referring to FIGS. 1 to 3 again, a method for producing a separator 1 in accordance with Embodiment 3 of the present invention.

A method for producing the separator 1 that includes (i) a base material 2 and (ii) a functional layer 3 that is provided to at least one of surfaces of the base material 2 includes a withstand voltage inspection carried out with respect to the separator 1 for detecting a defect in the separator 1. The method for producing the separator 1 is regarded as the method for producing the separator 1 in accordance with Embodiment 3 of the present invention.

According to the method for producing the separator 1 in accordance with Embodiment 3 of the present invention, it is possible to easily detect an extremely small defect of an order of not more than several hundred μm, the extremely small defect having been developed in the separator 1. Examples of the extremely small defect include a slit 4, a pinhole 5, a recess 6, a slit 7, and a defect 12. The roller-derived defects described earlier are also encompassed in the extremely small defect. In particular, an optical inspection carried out with respect to the separator 1 is unsuitable for detecting the recess 6 provided to the separator 1. Note, however, that the withstand voltage inspection carried out with respect to the separator 1 makes it easy to detect the recess 6.

The withstand voltage inspection is carried out with respect to the separator 1 by causing an electrode 10 and an electrode 11 that face each other across the separator 1 to be electrically connected with each other. In a part of the separator 1 which part is sandwiched by the electrode 10 and the electrode 11, a value of a voltage to be applied to each of the electrode 10 and the electrode 11 is determined so that (i) the electrode 10 and the electrode 11 are not electrically connected with each other in a case where no defect 12 is present and (ii) the electrode 10 and the electrode 11 are electrically connected with each other in a case where the defect 12 is present. This makes it possible to accurately detect an extremely small defect of an order of not more than several hundred μm, the extremely small defect having been developed in the separator 1, so that the recess 6 is easily detected.

A constant direct-current voltage is preferably applied to each of the electrode 10 and the electrode 11. This makes it possible to (i) continuously apply, to each of the electrode 10 and the electrode 11, a voltage having a desired value and (ii) allow the electrode 10 and the electrode 11 to be electrically connected with each other under a constant condition. Thus, the withstand voltage inspection can be carried out with respect to the separator 1 under a continuous and constant condition.

In the withstand voltage inspection carried out with respect to the separator 1, a hole or a depression that is provided to at least one of the base material 2 and the functional layer 3 is detected. Furthermore, in the withstand voltage inspection carried out with respect to the separator 1, the defect 12 is preferably detected in the separator 1 that includes, as the functional layer 3, a heat-resistant film that contains aramid as a main component, a film that contains ceramic as a main component, or a film that contains PVdF as a main component.

An apparatus for producing the separator 1 in accordance with Embodiment 3 of the present invention includes an electric power source 9, the electrode 10, and the electrode 11. Configurations of the apparatus for producing the separator 1 in accordance with Embodiment 3 of the present invention except for those of the electric power source 9, the electrode 10, and the electrode 11 can be achieved by a known technique, and a specific description thereof is therefore omitted here.

[Variation 1]

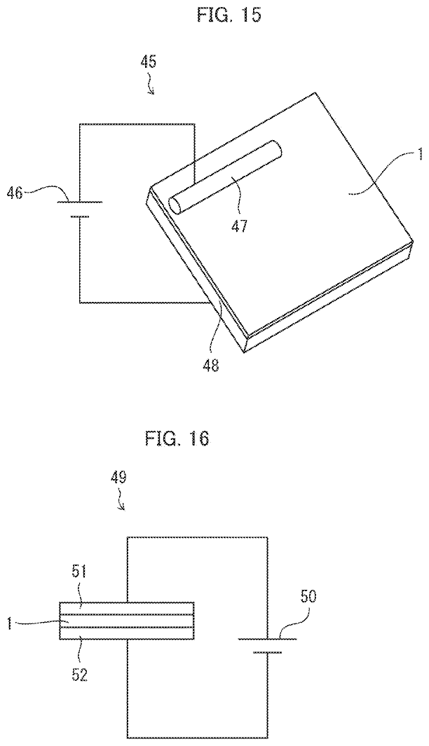

FIG. 15 is a perspective view schematically illustrating an inspection device 45 and an inspection method each for inspecting a separator 1 in accordance with Variation 1.

The inspection device 45 includes an electric power source 46, an electrode 47, and an electrode 48. The electric power source 46, the electrode 47, and the electrode 48 correspond to the electric power source 9 (see FIGS. 2 and 3), the electrode 10 (see FIGS. 2 and 3), and the electrode 11 (see FIGS. 2 and 3), respectively. FIG. 15 illustrates a case where a direct-current voltage is used. Alternatively, either a direct-current voltage or an alternating-current voltage can be applied to the electrode 47 and the electrode 48. In FIG. 15, the electrode 47 is connected with a positive electrode of the electric power source 46, and the electrode 48 is connected with a negative electrode of the electric power source 46. Alternatively, the electrode 48 can be connected with the positive electrode of the electric power source 46, and the electrode 47 can be connected with the negative electrode of the electric power source 46. The electrode 47 has a cylindrical shape, and the electrode 48 has a plate-like shape. In FIG. 15, a withstand voltage inspection is carried out with respect to the separator 1 by providing the separator 1 on the electrode 48 and providing the electrode 47 on a first surface of the separator 1 which first surface is opposite from a second surface of the separator 1 on which second surface the electrode 48 is provided. The electrode 47, which has a cylindrical shape, can be moved so as to be rolled on the first surface of the separator 1 which first surface is opposite from the second surface of the separator 1 on which second surface the electrode 48 is provided. The electrode 47 can be moved with use of a device or manually. Both the electrode 47 and the electrode 48 are in contact with the separator 1 during the withstand voltage inspection carried out with respect to the separator 1. This allows an extremely small defect (e.g., the pinhole 5 (see FIG. 1)) to be detected in the separator 1 even in a case where the electrode 47 is moved at a relatively high speed.

The inspection device for inspecting the separator 1, the inspection device including the electric power source 9, the electrode 10, and the electrode 11, is configured such that the electrode 10 and the electrode 11 are fixed so that the separator 1 is moved. In contrast, the inspection device 45 is configured such that the separator 1 and the electrode 48 are fixed so that the electrode 47 is moved. A constant direct-current voltage is preferably applied to each of the electrode 47 and the electrode 48 for a reason similar to a reason for which a constant direct-current voltage is preferably applied to each of the electrode 10 and the electrode 11. The electrode 47 is not limited to any particular electrode provided that the electrode 47 is an electric conductor that is hard enough to prevent a crack in the electrode 47. The electrode 47 can be made of stainless steel (SUS), tungsten, electrically conductive ceramic, or the like. In contrast, the electrode 48 is preferably an electrically conductive non-metallic sheet. For example, the electrode 48 is preferably an electrically conductive rubber sheet.

According to the inspection device 45, it is unnecessary to transfer the separator 1 during the withstand voltage inspection carried out with respect to the separator 1. This makes it easy to inspect the separator 1 that has a large area. In order to carry out the withstand voltage inspection with respect to the separator 1 with use of the inspection device 45, it is necessary to tightly place the separator 1 on the electrode 48 so that no wrinkle appears on the separator 1.

In the third step described earlier, a part of the separator 1 which part corresponds to an unwound part 20 (see FIG. 5) can be cut so that the inspection device 45 is used to at least partially inspect the cut part of the separator 1 for a defect such as a roller-derived defect. In a case where no defect is detected, the cut part can be discarded, and the other part of the separator 1 can be slit. In a case where the defect is detected, it is possible to (i) inspect, for a similar defect, the separator 1 included in previous and subsequent lots and/or (ii) clean a roller 13. The unwound part 20 that extends in a machine direction of the separator 1 preferably has a length that is not less than a length of a circumference of a roller 13a (see FIG. 4). The length can be at least twice or at least three times the length of the circumference of the roller 13a. In a case where the length of the unwound part 20 that extends in the machine direction of the separator 1 is set to at least twice a length of a circumference of a roller that has a maximum diameter, detected defects are easily regarded as periodic defects.

The inspection device 45 can be used to inspect an inspected part 22 or slit separators 32 instead of the separator 1.

[Variation 2]

FIG. 16 is a front view schematically illustrating an inspection device 49 and an inspection method each for inspecting a separator 1 in accordance with Variation 2.

The inspection device 49 includes an electric power source 50, an electrode 51, and an electrode 52. The electric power source 50, the electrode 51, and the electrode 52 correspond to the electric power source 9 (see FIGS. 2 and 3), the electrode 10 (see FIGS. 2 and 3), and the electrode 11 (see FIGS. 2 and 3), respectively. The electrode 51 and the electrode 52 each have a plate-like shape. In FIG. 16, a withstand voltage inspection is carried out with respect to the separator 1 by providing the separator 1 so that the separator 1 is sandwiched between the electrode 51 and the electrode 52. Both the electrode 51 and the electrode 52 are in contact with the separator 1 during the withstand voltage inspection carried out with respect to the separator 1. FIG. 16 illustrates a case where a direct-current voltage is used. Alternatively, either a direct-current voltage or an alternating-current voltage can be applied to the electrode 51 and the electrode 52. In FIG. 16, the electrode 51 is connected with a positive electrode of the electric power source 50, and the electrode 52 is connected with a negative electrode of the electric power source 50. Alternatively, the electrode 52 can be connected with the positive electrode of the electric power source 50, and the electrode 51 can be connected with the negative electrode of the electric power source 50.

(a) of FIG. 17 is a perspective view illustrating a specific configuration example of the inspection device 49. (b) of FIG. 17 is a side view of the inspection device 49 when seen from a machine direction of the separator 1. The inspection device 49 includes an electric power source 50, an electrode 51, an electrode 52, a wall part 53, a wall part 54, a mount part 55, and a lifting and lowering section 56. For simplification of illustration, (b) of FIG. 17 illustrates neither the electric power source 50 nor the lifting and lowering section 56.

The wall part 53 and the wall part 54 are each provided so as to be parallel to the electrode 52. The wall part 53 and the wall part 54 are provided so as to face each other across the electrode 52. An upper surface of the electrode 52, the wall part 53, and the wall part 54 form a groove 57. A part of the separator 1 which part is to be subjected to a withstand voltage inspection is provided in the groove 57. The electrode 52 has, from a wall part 53 side end thereof to a wall part 54 side end thereof, a length that is equal to or slightly larger than a width of the separator 1, the width extending in a transverse direction of the separator 1. A length, extending in a shorter side direction, of each of the electrode 51 and the electrode 52 is not limited to any particular length. Note, however, that, the electrode 51 can be made shorter in length extending in the shorter side direction than the electrode 52 as illustrated in (b) of FIG. 17 so that a short circuit is prevented from occurring due to a contact between the electrode 51 and the electrode 52.

The mount part 55 mounts thereon the electrode 51. The electrode 51 is provided on an electrode 52 side of the mount part 55 so as to face the electrode 52. The electrode 51 has a size and a shape that allow the electrode 51 to be fitted in the groove 57. The lifting and lowering section 56 is a mechanism that lifts and lowers the mount part 55 that mounts thereon the electrode 51. In a case where the lifting and lowering section 56 lowers the mount part 55 while the electrode 51 is not fitted in the groove 57, the electrode 51, together with the mount part 55, is lowered and then fitted in the groove 57. In contrast, in a case where the lifting and lowering section 56 lifts the mount part 55 while the electrode 51 is fitted in the groove 57, the electrode 51, together with the mount part 55, is lifted and then left from the groove 57.

The withstand voltage inspection is carried out with respect to the separator 1 by placing the separator 1 on the upper surface of the electrode 52 so that the separator 1 is substantially precisely fitted in the groove 57. This determines a position of the separator 1 with respect to the electrode 52. By causing the lifting and lowering section 56 to lower the mount part 55 in such a state so that the electrode 51 is fitted in the groove 57, the separator 1 can be sandwiched by the electrode 51 and the electrode 52. In this case, a position of the electrode 51 in a direction parallel to a surface of the separator 1 is defined in advance by the mount part 55 and the lifting and lowering section 56. Thus, a position of the electrode 51 with respect to the separator 1 is determined when the mount part 55 finishes descending.

According to the inspection device 49 illustrated in FIG. 17, a part of the separator 1 which part is to be subjected to the withstand voltage inspection can be positioned with respect to the electrode 51 and the electrode 52.

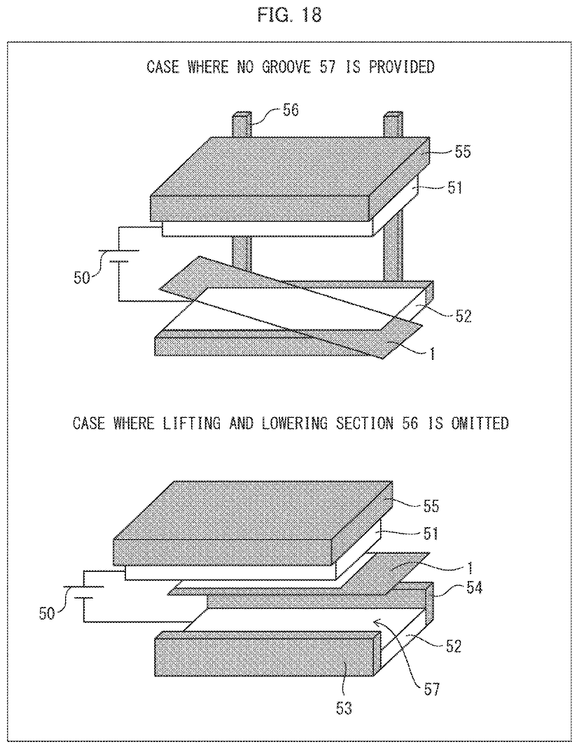

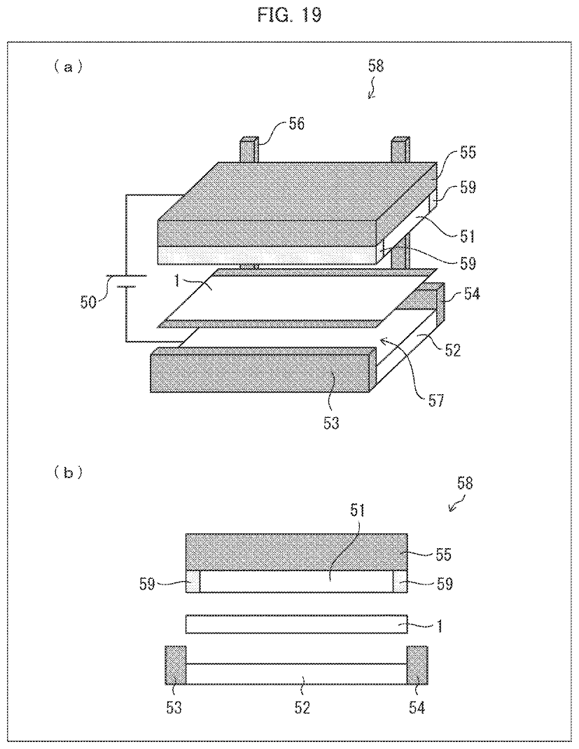

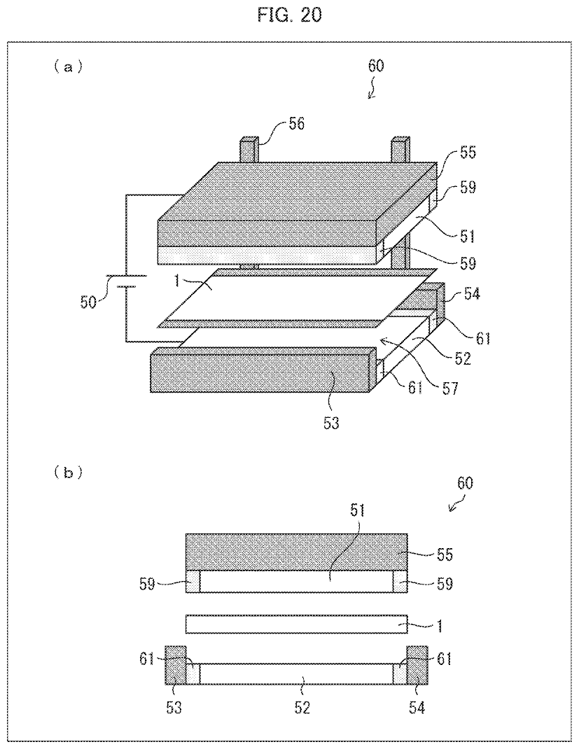

FIG. 18 has perspective views illustrating respective configurations of two devices each serving as a comparative example of the inspection device 49 illustrated in FIG. 17.

In a case where the wall part 53 and the wall part 54 are omitted from the inspection device 49 illustrated in FIG. 17 and no groove 57 is provided, the separator 1 freely moves on the electrode 52. This makes it difficult to determine the position of the separator 1 with respect to the electrode 52.

In a case where the lifting and lowering section 56 is omitted from the inspection device 49 illustrated in FIG. 17, it is difficult to determine the position of the electrode 51 in the direction parallel to the surface of the separator 1. This causes the electrode 51 to be positionally displaced with respect to the separator 1 and/or the electrode 52. Furthermore, in a case where the electrode 51 is obliquely fitted in the groove 57, the electrode 51 collides with the wall part 53 and/or the wall part 54, so that the electrode 51 is damaged.

(a) of FIG. 19 is a perspective view illustrating an inspection device 58, which is a variation of the inspection device 49. (b) of FIG. 19 is a side view of the inspection device 58 when seen from the machine direction of the separator 1. The inspection device 58 illustrated in each of (a) and (b) of FIG. 19 differ from the configuration of a corresponding one of (a) and (b) of FIG. 17 in that the inspection device 58 includes insulators 59 provided in respective both edges of the electrode 51 which edges extend in a longer side direction of the electrode 51. The configuration makes it possible to further restrain the electrode 51 and the electrode 52 from being short-circuited due to a contact therebetween.

(a) of FIG. 20 is a perspective view illustrating an inspection device 60, which is another variation of the inspection device 49. (b) of FIG. 20 is a side view of the inspection device 60 when seen from the machine direction of the separator 1. The inspection device 60 illustrated in each of (a) and (b) of FIG. 20 differ from the configuration of a corresponding one of (a) and (b) of FIG. 17 in that the inspection device 60 includes (i) insulators 59 provided in respective both edges of the electrode 51 which edges extend in the longer side direction of the electrode 51 and (ii) insulators 61 provided in respective both edges of the electrode 52 which edges extend in the longer side direction of the electrode 52. The configuration makes it possible to further restrain the electrode 51 and the electrode 52 from being short-circuited due to a contact therebetween.

The inspection device 49 can be used to inspect an inspected part 22 or slit separators 32 instead of the separator 1.

Aspects of the present invention can also be expressed as follows:

A method for producing a separator in accordance with an aspect of the present invention includes: an inspection step of inspecting the separator, the inspection step including the steps of: a) transferring the separator via a plurality of rollers so as to prepare a roll obtained by winding the separator; b) unwinding part of the separator from the roll; c) carrying out an inspection for a defect with respect to at least part of an unwound part of the separator; and d) determining quality of the roll in accordance with a result of the inspection.

According to the method, defects that are periodically developed in a machine direction of the separator can be detected without the need to unwind all the separator from the roll. Thus, in a case where periodic defects are expected to be developed in the separator of the roll, the inspection step can be carried out with high efficiency.

The method in accordance with an aspect of the present invention is configured such that the inspection is a withstand voltage inspection carried out with respect to the separator.

According to the method, it is possible to easily detect an extremely small defect having been produced in the separator and having not more than several hundred μm. Furthermore, the method allows an extremely small defect to be detected in the separator even in a case where the separator is transferred at a relatively high speed via the plurality of rollers. Thus, the method is suitable for detecting a defect in the separator while transferring the separator.

The method in accordance with an aspect of the present invention is configured such that at least a part of the unwound part of the separator which part has been subjected to the inspection is discarded.

In a case where a foreign object has adhered to a surface of a roller via which to transfer an inspected part of the separator, or in a case where a flaw is developed in the surface of the roller, a defect that is unique to the inspected part may be developed in the inspected part. According to the method, by discarding the inspected part, it is possible to remove, from the separator, a part in which a defect may be developed due to (i) a foreign object having adhered to the surface of the roller or (ii) a flaw developed in the surface of the roller. Furthermore, in a case where a change in physical property of the inspected part may be caused, a part in which a change in physical property may be caused by the inspection can be removed from the separator by discarding the inspected part.

The method in accordance with an aspect of the present invention is configured such that in the step b), the separator is unwound for a length that is not less than a length of a circumference of a roller that has a maximum diameter of the plurality of rollers.

According to the method, periodic defects that are developed in the separator are easily located in a part of the separator which part has been unwound. In a case where a part of the unwound part of the separator which part has a length as long as or longer than the circumference of the roller is inspected, such defects are easily detected. This allows the inspection to be carried out through the step c) with higher accuracy.

A method in accordance with an aspect of the present invention further includes: in the step d), attaching, to the roll that has been regarded as a non-defective product, a label indicating that the roll is a non-defective product.

The method makes it possible to understand, from the label, whether the roll is a non-defective product.

The method in accordance with an aspect of the present invention is configured such that the label includes information on the roll which information has been revealed after the step c).

The method makes it possible to understand, from the label, information on the roll.

An apparatus for producing a separator in accordance with an aspect of the present invention includes: a winding device for unwinding the separator from a roll obtained by winding the separator; an inspection performing device for carrying out an inspection for a defect with respect to at least part of an unwound part of the separator; and a cutting device for cutting the separator so as to remove a part of the separator which part has been subjected to the inspection, the winding device winding back, to the roll, a part of the unwound part of the separator which part is continuous with the roll after the separator is cut.

With the configuration, the separator can be partially unwound from the roll in a case where at least part of an unwound part of the separator is inspected for a defect by partially unwinding the separator from the roll. The configuration also allows the cutting device to cut, from an uninspected part of the separator, the inspected part of the separator to be discarded. This makes it possible to achieve an apparatus for producing the separator, the apparatus being suitable for a highly efficient inspection step.

The apparatus in accordance with an aspect of the present invention is configured such that the inspection performing device subjects the separator to a withstand voltage inspection carried out for detecting a defect in the separator.

According to the configuration, it is possible to easily detect an extremely small defect of an order of not more than several hundred μm, the extremely small defect having been developed in the separator. Furthermore, the configuration allows an extremely small defect to be detected in the separator even in a case where the separator is transferred at a relatively high speed via the plurality of rollers. Thus, the configuration is suitable for detecting a defect in the separator while transferring the separator.

The apparatus in accordance with an aspect of the present invention is configured such that the winding device unwinds the separator for a length that is not less than a length of a circumference of a roller that has a maximum diameter of a plurality of rollers via which to transfer the separator.

According to the configuration, periodic defects that are developed in the separator are easily located in a part of the separator which part has been unwound. In a case where a part of the unwound part of the separator which part has a length as long as or longer than the circumference of the roller is inspected, such defects are easily detected. This allows the inspection to be carried out through the step c) with higher accuracy.

The present invention is not limited to the embodiments, but can be altered by a skilled person in the art within the scope of the claims. The present invention also encompasses, in its technical scope, any embodiment derived by combining technical means disclosed in differing embodiments.

### REFERENCE SIGNS LIST

1 Separator
2 Base material
3 Functional layer
4, 7 Slit (defect)
5 Pinhole (defect)
6 Recess (defect)
10, 11, 24, 25, 42, 43, 47, 48, 51, 52 Electrode
12 Defect
13, 13a, 26, 33, 39, 80 Roller
14, 18 Winding device
17, 31, 44 Roll
20 Unwound part
21 Inspection performing device
22 Inspected part
27 Defect
28 Cutting device
29 Label
30 Separator piece
32 Slit separator
34 Slitting device
35 Preinspection device
40, 45, 49, 58, 60 Inspection device
59, 61 Insulator

1. A method for producing a separator, comprising:
an inspection step of inspecting the separator,
the inspection step including the steps of:
a) transferring the separator via a plurality of rollers so as to prepare a roll obtained by winding the separator;
b) unwinding part of the separator from the roll;
c) carrying out an inspection for a defect with respect to at least part of an unwound part of the separator; and
d) determining quality of the roll in accordance with a result of the inspection.

2. The method as set forth in claim 1, wherein the inspection is a withstand voltage inspection carried out with respect to the separator.

3. The method as set forth in claim 1, wherein at least a part of the unwound part of the separator which part has been subjected to the inspection is discarded.

4. The method as set forth in claim 1, wherein in the step b), the separator is unwound for a length that is not less than a length of a circumference of a roller that has a maximum diameter of the plurality of rollers.

5. A method as set forth in claim 1, further comprising:
in the step d), attaching, to the roll that has been regarded as a non-defective product, a label indicating that the roll is a non-defective product.

6. The method as set forth in claim 5, wherein the label includes information on the roll which information has been revealed after the step c).

7. An apparatus for producing a separator, comprising:
a winding device for unwinding the separator from a roll obtained by winding the separator;
an inspection performing device for carrying out an inspection for a defect with respect to at least part of an unwound part of the separator; and
a cutting device for cutting the separator so as to remove a part of the separator which part has been subjected to the inspection,
the winding device winding back, to the roll, a part of the unwound part of the separator which part is continuous with the roll after the separator is cut.

8. The apparatus as set forth in claim 7, wherein the inspection performing device subjects the separator to a withstand voltage inspection carried out for detecting a defect in the separator.

9. The apparatus as set forth in claim 7, wherein the winding device unwinds the separator for a length that is not less than a length of a circumference of a roller that has a maximum diameter of a plurality of rollers via which to transfer the separator.
